(19) United States
(12) Patent Application Publication
(10) Pub. No.: US 2007/0093055 A1
(43) Pub. Date: Apr. 26, 2007

(54) HIGH-ASPECT RATIO CONTACT HOLE AND METHOD OF MAKING THE SAME

(76) Inventors: Pei-Yu Chou, Taipei Hsien (TW); Jiunn-Hsiung Liao, Tainan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/163,597

(22) Filed: Oct. 24, 2005

(51) Int. Cl. H01L 21/4763; H01L 21/44

(52) U.S. Cl. 438/638; 438/637; 438/640; 438/666

(57) ABSTRACT

A substrate has thereon a conductive region to be partially exposed by the contact hole, a contact etch stop layer overlying the substrate and covering the conductive region, and an inter-layer dielectric (ILD) layer on the contact etch stop layer. A photoresist pattern is formed on the ILD layer. The photoresist pattern has an opening directly above the conductive region. Using the photoresist pattern as an etch hard mask and the contact etch stop layer as an etch stop, an anisotropic dry etching process is performed to etch the ILD layer through the opening, thereby forming an upper hole region. The photoresist pattern is removed. An isotropic dry etching process is performed to dry etching the contact etch stop layer selective to the ILD layer through the upper hole region, thereby forming a widened, lower contact bottom that exposes an increased surface area of underlying conductive region.

### BACKGROUND OF THE INVENTION

1. Field of the Invention

The present invention relates to a method of forming contact holes of semiconductor device and, more particularly, to a method of fabricating a high-aspect ratio (aspect ratio>30) contact hole having a widened contact bottom to reduce contact sheet resistance.

2. Description of the Prior Art

The trend to micro-minituriaztion, or the ability to fabricate semiconductor devices with features smaller than 0.1 micrometers, has presented difficulties when attempting to form narrow diameter, deep (high aspect ratio) contact holes in a dielectric layer, to expose underlying conductive regions.

The use of photoresist as a mask for etching of a thick dielectric layer presents selectivity concerns in regards to a fast removal etch rate of the photoresist in the dielectric layer etching ambient, therefore not allowing only the photoresist shape to be used as the etch mask. Increasing the thickness of the photoresist mask to accommodate the non-selectivity of etch ambient adversely affects the resolution needed to define deep, narrow diameter openings.

As the feature size of the integrated circuit shrinks to below 100 nm, it becomes a major challenge to form a contact device having sufficient low contact sheet resistance. FIGS. 1-4 are schematic, cross-sectional diagrams showing the process of making a high aspect ratio contact hole in accordance with the prior art method. As shown in FIG. 1, a metal-oxide-semiconductor (MOS) transistor device 20 is formed on a semiconductor substrate 10.

The MOS transistor device 20, which is isolated by shallow trench isolation (STI) 24, comprises source/drain regions 12, gate electrode 14, and spacers 16 on sidewalls of the gate electrode 14. A contact etch stop layer (CESL) 32 such as silicon nitride is deposited over the MOS transistor device 20 and the semiconductor substrate 10. An inter-layer dielectric (ILD) layer 34 having a thickness of about 2,500-6,000 angstroms is deposited on the contact etch stop layer 32. A bottom anti-reflective coating (BARC) layer 36 is deposited on the ILD layer 34. A photoresist layer 40 is formed on the BARC layer 36. Conventional lithography processes are carried out to form openings 42 in the photoresist layer 40.

As shown in FIG. 2, using the photoresist layer 40 as an etching hard mask, the exposed BARC layer 36 and the ILD layer 34 are etched away through the openings 42 so as to form openings 52. Typically, the etching of the ILD layer 34 is implemented by using anisotropic dry etching. The etching of the ILD layer 34 stops on the contact etch stop layer 32.

Subsequently, as shown in FIG. 3, using the remaining photoresist layer 40 and the BARC layer 36 as an etching hard mask, the exposed contact etch stop layer 32 is then in-situ anisotropically etched away through the openings 52, thereby forming contact holes 62. As shown in FIG. 4, the remaining hard mask over the ILD layer 32 is removed.

The above-described prior art method of forming contact hole has several drawbacks. First, the ILD layer 34 and the underlying CESL layer 32 are etched in-situ, without removing the photoresist layer 40. The polymer residue produced during the etching of the ILD layer and the CESL layer 32 results in a tapered profile of the contact hole 62, thereby reducing the exposed surface area of the source/drain region 12 and increased contact sheet resistance. Second, when etching the CESL layer 32, the contact profile is also impaired due to the low selectivity between silicon nitride and silicon oxide.

In light of the above, there is a need in this industry to provide an improved method of fabricating a high aspect ratio contact hole and contact device which has reduced contact sheet resistance without affecting the contact profile formed in the ILD layer.

### SUMMARY OF THE INVENTION

It is the primary object of the present invention to provide an improved method of fabricating a high aspect ratio contact hole and contact device, which has reduced contact sheet resistance.

It is another object of the present invention to provide a method of making a contact device having a reverse T-shaped contact bottom without affecting the contact profile formed in the inter-layer dielectric layer.

According to the claimed invention, from one aspect, a method of fabricating contact hole of semiconductor device is disclosed. A substrate has thereon a conductive region to be partially exposed by the contact hole, a contact etch stop layer overlying the substrate and covering the conductive region, and an inter-layer dielectric (ILD) layer on the contact etch stop layer. A photoresist pattern is formed on the ILD layer. The photoresist pattern has an opening therein. The opening is situated directly above the conductive region. Using the photoresist pattern as an etch hard mask and the contact etch stop layer as an etch stop, an anisotropic dry etching process is performed to etch the ILD layer through the opening, thereby forming an upper hole region. The photoresist pattern is then stripped off. An isotropic dry etching process is then performed to isotropically dry etching the contact etch stop layer selective to the ILD layer through the upper hole region, thereby forming a widened, lower contact bottom that exposes an increased surface area of underlying conductive region. The upper hole region and the widened lower contact bottom constitute the contact hole.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-4 are schematic, cross-sectional diagrams showing the process of making a high aspect ratio contact hole in accordance with the prior art method;

FIGS. 5-8 are schematic, cross-sectional diagrams showing the process of making a high aspect ratio contact hole in accordance with the preferred embodiment of this invention; and

FIG. 9 is an enlarged cross-sectional view showing the reverse T-shaped contact bottom in accordance with the preferred embodiment of this invention.

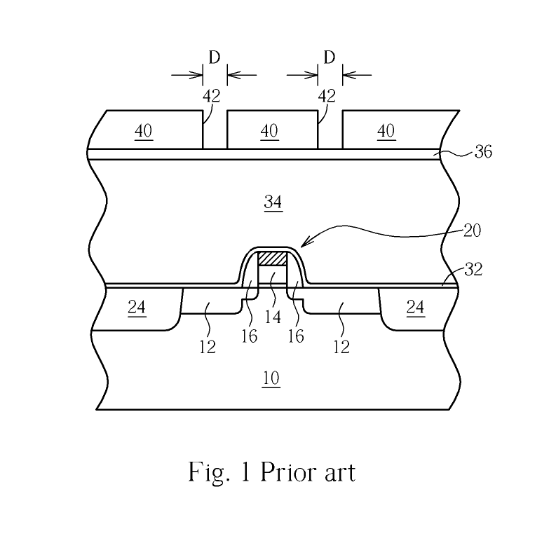

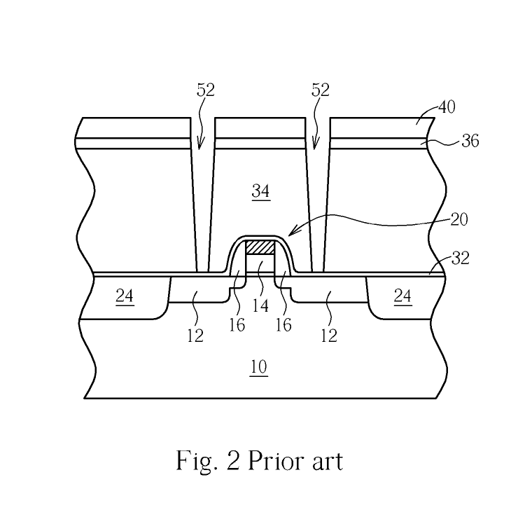

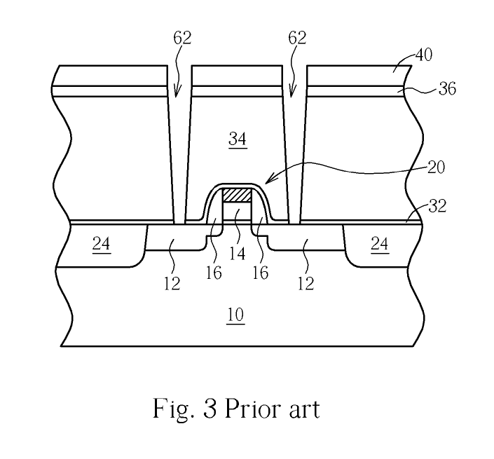

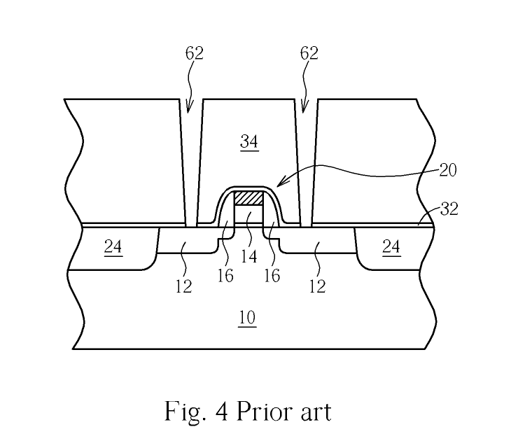

### DETAILED DESCRIPTION

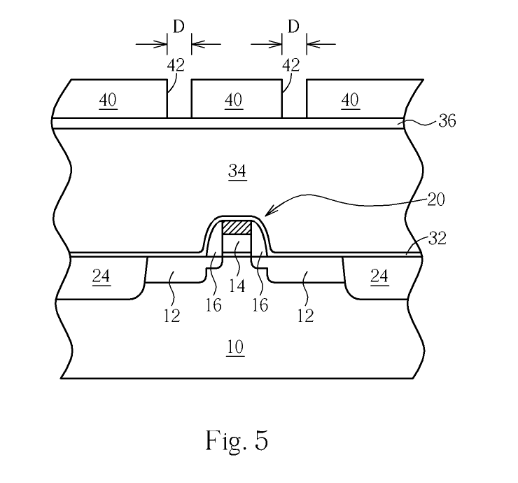

In describing the preferred embodiment of the present invention, reference will be made herein to FIGS. 5-9 of the drawings. Features of the invention are not necessarily drawn to scale in the drawings.

Please refer to FIGS. 5-8. FIGS. 5-8 are schematic, cross-sectional diagrams showing the process of making a high aspect ratio contact hole in accordance with the preferred embodiment of this invention. The term “aspect ratio” is defined as the depth of a contact hole to the diameter of the contact hole. The term “high aspect ratio” means an aspect ratio that is greater than 30. It is appreciated that the term “contact hole” comprises through holes, via holes or contact openings formed in the semiconductor device for the purpose of electrically connecting two conductive layers that are in different levels, for example.

As shown in FIG. 5, a metal-oxide-semiconductor (MOS) transistor device 20 is formed on a semiconductor substrate 10. It is understood that this invention may be applied to form via hole or contact hole that exposes a portion of the underlying conductive layer such as word lines or interconnect, in which a layer of contact etch stop is involved.

According to the exemplary preferred embodiment, the MOS transistor device 20, which is isolated by shallow trench isolation (STI) 24, comprises source/drain regions 12, gate electrode 14, and spacers 16 on sidewalls of the gate electrode 14. Each source/drain region may further comprise a surface silicide layer or salicide layer such as nickel silicide (not shown). A contact etch stop layer (CESL) 32 such as silicon nitride is deposited over the MOS transistor device 20 and the semiconductor substrate 10. The contact etch stop layer 32 has a thickness of about 200-1,000 angstroms. An inter-layer dielectric (ILD) layer 34 having a thickness of about 2,500-6,000 angstroms is deposited on the contact etch stop layer 32.

The ILD layer 34 may comprise un-doped silicon glass such as tetraethylorthosilicate (TEOS) oxide, and doped silicon oxide such as borophosphosilicate glass (BPSG), FSG, PSG or BSG. Plasma-enhanced chemical vapor deposition (PECVD) methods may be used to deposit such ILD layer.

A bottom anti-reflective coating (BARC) layer 36 such as silicon oxy-nitride is deposited on the ILD layer 34. The BARC layer 36 has a thickness of about 200-600 angstroms, preferably 300 angstroms. A photoresist layer 40 is then formed on the BARC layer 36. Conventional lithography processes are carried out to form openings 42 in the photoresist layer 40, featuring a diameter D of about 0.1 micrometer.

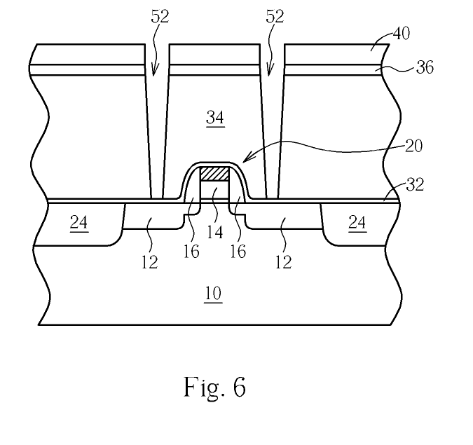

As shown in FIG. 6, using the photoresist layer 40 as an etching hard mask, the exposed BARC layer 36 and the ILD layer 34 are anisotropically etched away through the openings 42 so as to form openings 52. According to the preferred embodiment of this invention, the etching of the ILD layer 34 is implemented by anisotropic dry etching techniques employing C₄F₆/O₂/Ar or C₅F₈/CO/O₂/Ar as etching gas. The etching of the ILD layer 34 stops on the contact etch stop layer 32. With the presence of the photoresist layer 40 during the etching of the openings 52, polymer residue produces and renders the profile of the resultant openings 52 slightly tapered.

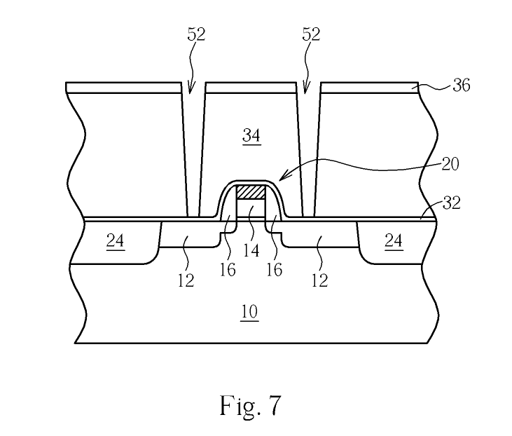

Subsequently, as shown in FIG. 7, after the formation of the openings 52, the remaining photoresist layer 40 is stripped off. In another embodiment, the BARC layer 36 is also removed. According to the preferred embodiment of this invention, the photoresist layer 40 is removed by using oxygen plasma ashing methods, followed by conventional wet cleaning treatment such as post-etch residue cleaning bath and de-ionized (DI) water quick dump rinse, and the like.

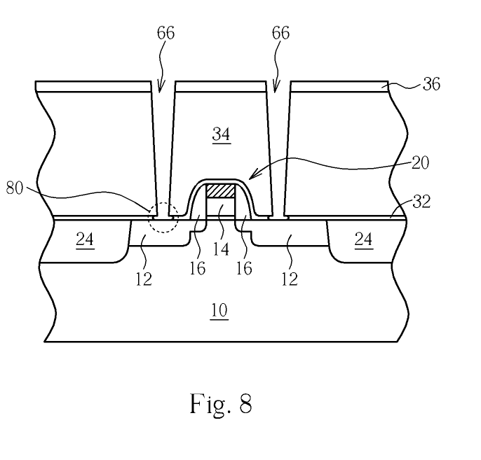

As shown in FIG. 8, an isotropic dry etching employing CH₂F₂/O₂/Ar or CHF₃/O₂/Ar as etching gas at a chamber pressure of greater than 30 mTorr is carried out to isotropically etch the exposed contact etch stop layer 32 through the openings 52, thereby forming contact holes 66 having a widened contact bottom (as indicated by dash line region 80).

It is noteworthy that the degree of anisotropy of the dry etching process directly relates to the dominant chamber pressure. Lowering the chamber pressure makes the dry etching process more anisotropic, while increasing the chamber pressure makes the dry etching process more isotropic. To isotropically etch the exposed contact etch stop layer 32 through the openings 52 employing CH₂F₂/O₂/Ar as etching gas, a chamber pressure of greater than 30 mTorr is necessary. It is advantageous to use the present invention because the widened contact bottom increases the footprint of the contact device, thereby reducing the contact sheet resistance thereof.

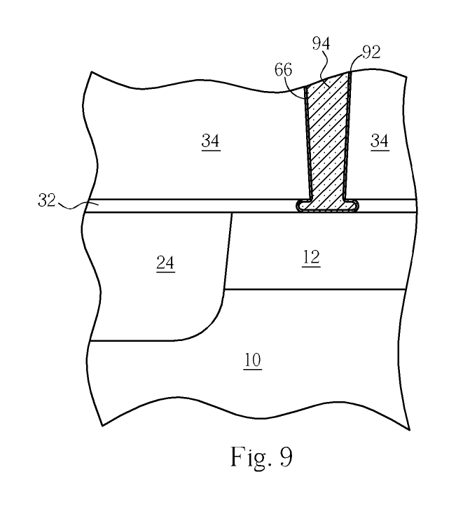

Please refer to FIG. 9. FIG. 9 is an enlarged cross-sectional view of dash line region 80 in FIG. 8 showing the reverse T-shaped contact bottom in accordance with the preferred embodiment of this invention. As shown in FIG. 9, after the isotropic etching of the contact etch stop layer 32, an atomic layer deposition (ALD) process is carried out to deposit a conformal layer of barrier material 92 such as Ti/TiN on the interior surface of the contact hole 66. Subsequently, a metal layer 94 is deposit on the barrier 92 to fill the contact hole 66.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A reverse T-shaped contact hole, comprising:
a substrate having thereon a conductive region;
a contact etch stop layer overlying said substrate and covering said conductive region;
an inter-layer dielectric (ILD) layer on said contact etch stop layer;
an upper hole region having slightly tapered profile formed in said ILD layer; and
a widened, lower contact bottom said formed in said contact etch stop layer, wherein said lower contact bottom exposes an increased surface area of underlying said conductive region, and wherein said upper hole region and said widened lower contact bottom constitute said reverse T-shaped contact hole.

2. The reverse T-shaped contact hole according to claim 1 wherein said conductive region is a source/drain region of a metal-oxide-semiconductor (MOS) transistor device.

3. The reverse T-shaped contact hole according to claim 2 wherein said source/drain region further comprises silicide/salicide layer formed on its surface.

4. The reverse T-shaped contact hole according to claim 1 wherein said conductive region is a gate of a MOS transistor device.

5. The reverse T-shaped contact hole according to claim 1 wherein an anti-reflection coating layer is situated on said ILD layer.

6. The reverse T-shaped contact hole according to claim 5 wherein said anti-reflection coating layer has a thickness of about 200-600 angstroms.

7. The reverse T-shaped contact hole according to claim 5 wherein said anti-reflection coating layer comprises silicon oxy-nitride.

8. The reverse T-shaped contact hole according to claim 1 wherein said contact etch stop layer comprises silicon nitride.

9. The reverse T-shaped contact hole according to claim 1 wherein said ILD layer comprises un-doped silicon glass and doped silicon oxide.

10. A method of fabricating a reverse T-shaped contact hole of semiconductor device, comprising:
providing a substrate having thereon a conductive region to be partially exposed by said contact hole, a contact etch stop layer overlying said substrate and covering said conductive region, and an inter-layer dielectric (ILD) layer on said contact etch stop layer;
forming a photoresist pattern on said ILD layer, said photoresist pattern having an opening therein directly above said conductive region;
using said photoresist pattern as an etch hard mask and said contact etch stop layer as an etch stop, performing an anisotropic dry etching process to etch the ILD layer through said opening, thereby forming an upper hole region;
stripping said photoresist pattern; and
performing an isotropic dry etching process to isotropically dry etching said contact etch stop layer selective to said ILD layer through said upper hole region, thereby forming a widened, lower contact bottom that exposes an increased surface area of underlying said conductive region, wherein said upper hole region and said widened lower contact bottom constitute said reverse T-shaped contact hole.

11. The method according to claim 10 wherein said conductive region is a source/drain region of a metal-oxide-semiconductor (MOS) transistor device.

12. The method according to claim 11 wherein said source/drain region further comprises silicide/salicide layer formed on its surface.

13. The method according to claim 10 wherein said conductive region is a gate of a MOS transistor device.

14. The method according to claim 10 wherein before forming said photoresist pattern on said ILD layer, a bottom anti-reflection coating (BARC) layer is formed on said ILD layer.

15. The method according to claim 14 wherein said BARC layer has a thickness of about 200-600 angstroms.

16. The method according to claim 14 wherein said BARC layer comprises silicon oxy-nitride.

17. The method according to claim 10 wherein said anisotropic dry etching process for etching the ILD layer is implemented by employing C₄F₆/O₂/Ar or C₅F₈/CO/O₂/Ar as etching gas.

18. The method according to claim 10 wherein said isotropic dry etching process for etching the contact etch stop layer is implemented by employing CH₂F₂/O₂/Ar or CHF₃/O₂/Ar as etching gas at a chamber pressure of greater than 30 mTorr.

19. The method according to claim 10 wherein said contact etch stop layer comprises silicon nitride.

20. The method according to claim 10 wherein said ILD layer comprises un-doped silicon glass and doped silicon oxide.

21. The method according to claim 10 further comprising a step of wet cleaning said upper hole region after removing said photoresist pattern.

22. The method according to claim 10 wherein said ILD layer has a thickness of about 2,500-6,000 angstroms.

23. The method according to claim 10 wherein said contact etch stop layer has a thickness of about 200-600 angstroms.

24. A reverse T-shaped contact device, comprising:
a substrate having thereon a conductive region, a contact etch stop layer overlying said substrate and covering said conductive region, and an inter-layer dielectric (ILD) layer on said contact etch stop layer;
an upper hole region having slightly tapered profile formed in said ILD layer;
a widened, lower contact bottom formed in said contact etch stop layer, wherein said lower contact bottom exposes an increased surface area of underlying said conductive region, and wherein said upper hole region and said widened, lower contact bottom constitute a reverse T-shaped contact hole;
a conformal layer of atomic layer deposition (ALD) barrier material deposited on interior surface of said contact hole; and
a metal material filling said reverse T-shaped contact hole.

25. The reverse T-shaped contact device according to claim 24 wherein said conductive region is a source/drain region of a metal-oxide-semiconductor (MOS) transistor device.

26. The reverse T-shaped contact device according to claim 25 wherein said source/drain region further comprises silicide/salicide layer formed on its surface.

27. The reverse T-shaped contact device according to claim 24 wherein said conductive region is a gate of a MOS transistor device.

28. The reverse T-shaped contact device according to claim 24 wherein said contact etch stop layer comprises silicon nitride.

29. The reverse T-shaped contact device according to claim 24 wherein said contact etch stop layer has a thickness of about 200-600 angstroms.

30. The reverse T-shaped contact device according to claim 24 wherein said ILD layer has a thickness of about 2,500-6,000 angstroms.

31. A method of fabricating reverse T-shaped contact device, comprising:
providing a substrate having thereon a conductive region, a contact etch stop layer overlying said substrate and covering said conductive region, and an inter-layer dielectric (ILD) layer on said contact etch stop layer;
forming a photoresist pattern on said ILD layer, said photoresist pattern having an opening therein directly above said conductive region;
using said photoresist pattern as an etch hard mask and said contact etch stop layer as an etch stop, performing an anisotropic dry etching process to etch the ILD layer through said opening, thereby forming an upper hole region having slightly tapered profile;
performing an isotropic dry etching process to isotropically dry etching said contact etch stop layer selective to said ILD layer through said upper hole region, thereby forming a widened, lower contact bottom that exposes an increased surface area of underlying said conductive region, wherein said upper hole region and said widened lower contact bottom constitute said contact hole;
performing an atomic layer deposition (ALD) process to deposit a conformal layer of barrier material on interior surface of said contact hole; and
filling said contact hole with a metal material.

32. The method according to claim 31 wherein before performing said isotropic dry etching process, said photoresist pattern is stripped off.

33. The method according to claim 31 wherein said conductive region is a source/drain region of a metal-oxide-semiconductor (MOS) transistor deivce.

34. The method according to claim 33 wherein said source/drain region further comprises silicide/salicide layer formed on its surface.

35. The method according to claim 31 wherein said conductive region is a gate of a MOS transistor device.

36. The method according to claim 31 wherein said anisotropic dry etching process for etching the ILD layer is implemented by employing C₄F₆/O₂/Ar or C₅F₈/CO/O₂/Ar as etching gas.

37. The method according to claim 31 wherein said isotropic dry etching process for etching the contact etch stop layer is implemented by employing CH₂F₂/O₂/Ar or CHF₃/O₂/Ar as etching gas at a chamber pressure of greater than 30 mTorr.

38. The method according to claim 31 wherein said contact etch stop layer comprises silicon nitride.

39. The method according to claim 31 wherein said contact etch stop layer has a thickness of about 200-600 angstroms.

40. The method according to claim 31 wherein said ILD layer has a thickness of about 2,500-6,000 angstroms.
